(19) United States
(12) Patent Application Publication
(10) Pub. No.: US 2018/0085700 A1
(43) Pub. Date: Mar. 29, 2018

(54) FILTER APPARATUS AND METHOD FOR DETERMINING PLUGGING OF FILTER APPARATUS

(71) Applicant: FUJITSU LIMITED, Kawasaki-shi (JP)

(72) Inventors: Hiroyoshi Sato, Oyama (JP); Hitoshi Suzuki, Oyama (JP); ICHIROU TAKAHASHI, Koga (JP)

(73) Assignee: FUJITSU LIMITED, Kawasaki-shi (JP)

(21) Appl. No.: 15/642,984

(22) Filed: Jul. 6, 2017

(30) Foreign Application Priority Data
Sep. 23, 2016 (JP) 2016-186026

(51) Int. Cl. B01D 46/00; G01N 15/08; G01N 27/00; H05K 7/20

(52) U.S. Cl. CPC B01D 46/0086; G01N 15/0806; G01N 27/00; G01N 2015/084; B01D 2279/45; B01D 2273/18; H05K 7/20181

(57) ABSTRACT

A filter apparatus includes a conductive housing disposed below an electronic device, to which a cooling air current is supplied from a lower side to an upper side, and including a bottom surface frame having a first opening and an upper surface frame having a second opening; terminals provided on the bottom surface and insulated from the housing; a filter including a filter part that removes dust of the air current and a filter frame retaining the filter; and an electric potential detecting part coupled to the terminals and configured to detect electric potentials of the terminals to detect a change of an electric potential, in a state in which the air current is supplied to the electronic device via the filter part, with respect to an electric potential in a state in which the filter frame is in contact with the bottom surface frame and the terminals.

### CROSS-REFERENCE TO RELATED APPLICATION

This present application is based upon and claims the benefit of priority of the prior Japanese Patent Application No. 2016-186026, filed on Sep. 23, 2016, the entire contents of which are incorporated herein by reference.

### FIELD

The embodiment discussed herein relates to a filter apparatus and a method for determining plugging of a filter apparatus.

A detecting apparatus for detecting plugging of a dust filter is known in the related art. The detecting apparatus includes the filter arranged in an air path of an air conditioner to remove dust by air-conditioned air, a displacement quantity detecting unit that contacts the filter to detect a movement state of the filter, and a supplied air quantity detecting unit that detects a physical quantity relating to a supplied air quantity of the air conditioner. The detecting apparatus detects the plugging of the filter when a displace quantity detected by the displacement quantity detecting unit is greater than or equal to a predetermined quantity in a state in which a value detected by the supplied air quantity detecting unit is a predetermined value.

A folder that contacts the filter and is movable together with the filter is arranged at an approximately central part of an air supply part of the air conditioner apparatus.

Because the above described detecting apparatus for detecting plugging of the dust filter detects the plugging at the approximately central part of the filter, the detecting apparatus can detect the plugging at the central part of the filter; however, the detecting apparatus may not accurately detect a situation of plugging in a case in which plugging of the filter is planarly distributed (biased).

### BACKGROUND

### Related-Art Documents

### Patent Documents

[Patent Document 1] Japanese Laid-open Patent Publication No. 2000-189738

### SUMMARY

According to an aspect of an embodiment, a filter apparatus includes a conductive housing disposed below an electronic device to which a cooling air current is supplied from a lower side to an upper side, the housing including a bottom surface frame having a first opening and including an upper surface frame having a second opening opposite to the first opening; a plurality of terminals provided on an upper surface side of the bottom surface frame of the housing, the plurality of terminals being insulated from the housing; a filter disposed inside the housing between the first opening and the second opening, the filter including a filter part configured to remove dust of the cooling air current and including a frame retaining a periphery of the filter part in a plan view; and an electric potential detecting part coupled to the plurality of terminals and configured to detect electric potentials of the plurality of terminals, the electric potential detecting part being configured to detect a change of an electric potential, in a state in which the cooling air current is supplied to the electronic device via the filter part, with respect to an electric potential in a state in which the filter frame is in contact with an upper surface of the bottom surface frame and the plurality of terminals.

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIG. 1 is a diagram illustrating a base station apparatus that includes a filter apparatus according to an embodiment;

FIG. 2 is a diagram illustrating a filter main unit;

FIG. 3 is a diagram illustrating the filter main unit;

FIG. 4 is a diagram illustrating a filter;

FIG. 5 is a diagram illustrating a sensor;

FIG. 6 is a diagram illustrating the sensor; and

FIG. 7 is a diagram illustrating a configuration of a monitoring system of the filter main unit and a monitoring control card.

### DESCRIPTION OF EMBODIMENT

Hereinafter, an embodiment will be described to which a filter apparatus and a method for determining plugging of a filter apparatus of the present invention are applied. One aspect of the embodiment is to provide a filter apparatus that can accurately detect a situation of plugging and a method for determining plugging of a filter apparatus.

### Embodiment

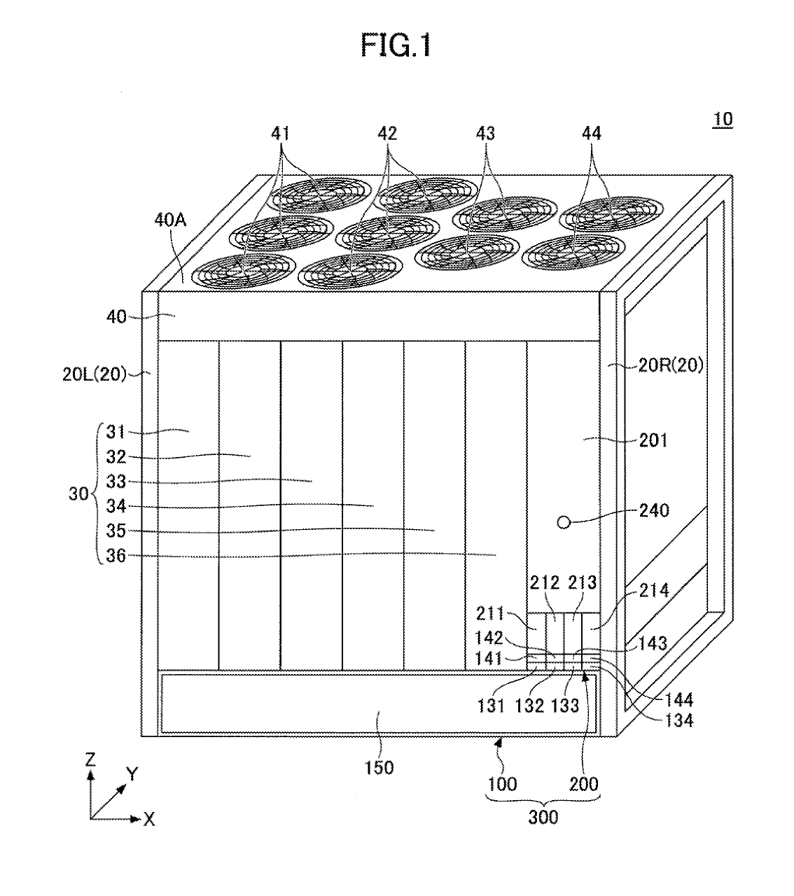

FIG. 1 is a diagram illustrating a base station apparatus 10 that includes a filter apparatus 300 according to an embodiment. In the following description, XYZ coordinates are defined. The Z axis extends along a vertical direction. Thus, a negative side in the Z axis direction is a lower side, and a positive side in the Z axis direction is an upper side. Further, a plan view means an XY plane viewed from the positive side in the Z axis direction.

The base station apparatus 10 includes a frame 20 (20L and 20R), a signal processing card 30 (31, 32, 33, 34, 35, and 36), a cooling fan 40, and the filter apparatus 300.

The frame 20 includes frame parts 20L and 20R. The frame parts 20L and 20R are rectangle frame shape members, and are fixed to each other by a fixing member such as a stay. The frame 20 is held (maintained) at a ground potential (frame ground potential).

To the frame 20, from bottom to top, a filter main unit 100 (lowermost part) of the filter apparatus 300, the signal processing card 30 (31, 32, 33, 34, 35, and 36) and a monitoring control card 200 (middle part) of the filter apparatus 300, and the cooling fan 40 (uppermost part) are fixed as three stacked parts.

Note that in the embodiment described here as an example, the frame 20 includes the frame parts 20L and 20R. However, the frame 20 may have any configuration that can hold the filter main unit 100, the signal processing card 30 (31, 32, 33, 34, 35, and 36), the monitoring control card 200, and the cooling fan 40. A rack or a cabinet including a shelf may be used instead of the frame 20.

The lowermost part, the middle part, and the uppermost part are terms used to describe a positional relationship between the configuration elements illustrated in FIG. 1 in the vertical direction. Hence, another configuration element such as a single processing card may be disposed below the filter main unit 100, and another configuration element such as a signal processing card may be disposed above the cooling fan 40, for example.

The filter apparatus 300 includes the filter main unit 100 and the monitoring control card 200. FIG. 1 illustrates terminals 131, 132, 133, and 134 of the filter main unit 100, conductive rubbers 141, 142, 143, and 144, and a filter 150. FIG. 1 also illustrates nodes 211, 212, 213, and 214 of the monitoring control card 200, and a warning lamp 240. The warning lamp 240 is provided on a front panel 201 of the monitoring control card 200.

The filter main unit 100 sucks in air from a lower side (e.g. below the lower surface of the filter main unit 100) through sucking power of the cooling fan 40, and removes dust and the like in the air through the filter 150 and discharges the air from the upper side to cool the signal processing card 30 (31, 32, 33, 34, 35, and 36). At this time, the monitoring control card 200 is also cooled.

The terminals 131, 132, 133, and 134 are insulated from each other. Similarly, the conductive rubbers 141, 142, 143, and 144 are insulated from each other, and the nodes 211, 212, 213, and 214 are insulated from each other. The conductive rubbers 141, 142, 143, and 144 are respectively attached on the terminals 131, 132, 133, and 134 through conductive adhesive agents or the like.

The terminals 131, 132, 133, and 134 are respectively in contact with the nodes 211, 212, 213, and 214 via the conductive rubbers 141, 142, 143, and 144, and are used when detecting plugging (clogging) of the filter 150. Note that in a case where the terminals 131, 132, 133, and 134 can be directly in contact with the nodes 211, 212, 213, and 214, the conductive rubbers 141, 142, 143, and 144 may be omitted.

Each of the conductive rubbers 141, 142, 143, and 144 is a member (material) in which a conductive material such as a metal powder or carbon black is mixed into elastic rubber.

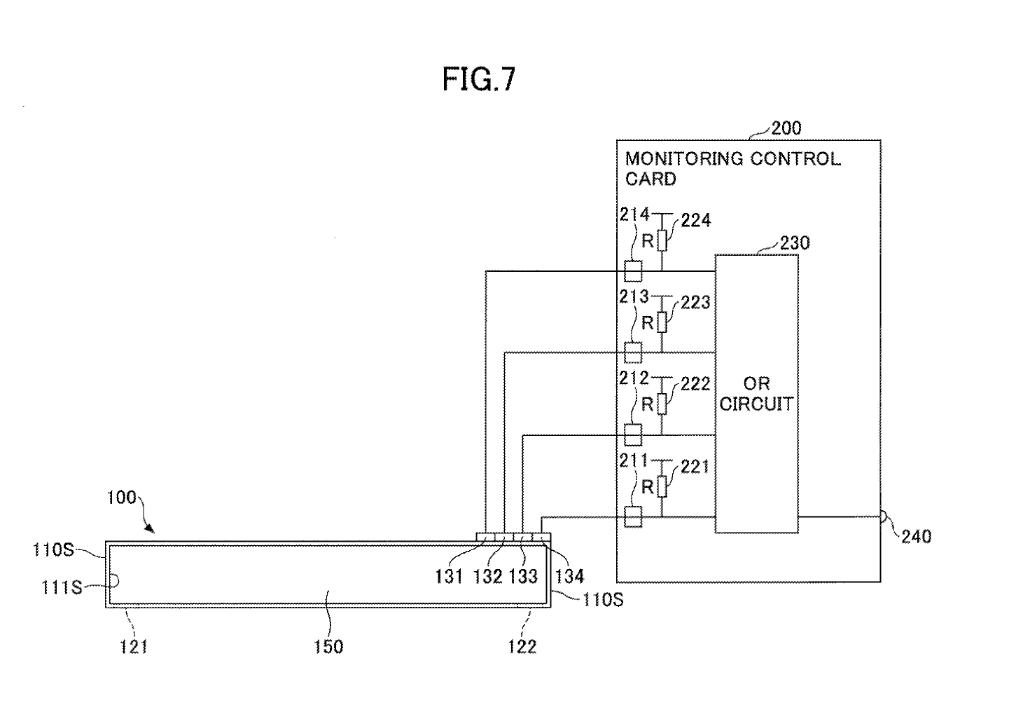

The monitoring control card 200 monitors plugging of the filter 150. The monitoring control card 200 has a size that is the same as each of the signal processing cards 31, 32, 33, 34, 35, and 36, and is disposed in the middle part of the frame 20. An internal configuration of the monitoring control card 200 will be described later below with reference to FIG. 7. The monitoring control card 200 monitors plugging of the filter 150 based on electric potentials detected via the nodes 211, 212, 213, and 214. The monitoring control card 200 lights up the warning lamp 240 when the plugging occurs. The warning lamp 240 is provided on the negative side surface of the monitoring control card 200 in the Y axis direction.

The signal processing card 30 can be divided (classified) into the six signal processing cards 31, 32, 33, 34, 35, and 36. The six signal processing cards 31, 32, 33, 34, 35, and 36 are respectively card-type information processing apparatuses having functions such as a baseband processing unit, a high way (HWY) interface processing unit, and a scheduler. Each of the signal processing cards 31 to 36 may have two or more functions. The signal processing cards 31, 32, 33, 34, 35, and 36 are an example of an electronic device. Note that the signal processing card may be divided for each function of the baseband processing unit, the high way (HWY) interface processing unit, and the scheduler.

The signal processing cards 31, 32, 33, 34, 35, and 36 are disposed at the middle part of the frame 20 together with the monitoring control card 200. The signal processing cards 31, 32, 33, 34, 35, and 36 and the monitoring control card 200 are inserted into the frame 20 from the negative side in the Y axis direction.

The cooling fan 40 includes fans 41, 42, 43, and 44. The cooling fan 40 rotationally drives the fans 41, 42, 43, and 44 to sucks in air from the negative side in the Z axis direction to the positive side in the Z axis direction. Thereby, the cooling fan 40 cools the signal processing card 30 (31, 32, 33, 34, 35, and 36) and the monitoring control card 200. That is, to the signal processing card 30 (31, 32, 33, 34, 35, and 36) and the monitoring control card 200, air (cooling air current) from which dust is removed by the filter main body 100 is supplied from the lower side to the upper side.

The fans 41, 42, 43, and 44 are arranged from the negative side to the positive side in the X axis direction. The three fans 41 and the three fans 42 are provided along the Y axis direction, and the two fans 43 and the two fans 44 are provided along the Y axis direction.

The number of fans 41 and 42 is different from the number of fans 43 and 44 because, for example, in the base station apparatus 10, at a negative side in the X axis direction where the fans 41 and 42 are located, a heat radiation amount of the signal processing card 30 and a required air volume are greater than a heat radiation amount of the signal processing card 30 and a required air volume at a positive side in the X axis direction where the fans 43 and 44 are located.

Further, in addition to or instead of dealing with differences (large versus small) of heat radiation amount through the numbers of fans 41, 42, 43, and 44, the base station apparatus 10 sets rotational speeds of the fans 41, 42, 43, and 44 in accordance with a distribution of heat radiation amount of the signal processing card 30 disposed inside the base station apparatus 10. Hence, the base station apparatus 10 sets the rotational speed to be higher for a location where the heat radiation amount is large, and sets the rotational speed to be lower for a location where the heat radiation amount is small.

In this way, the base station apparatus 10 sets the numbers and/or the rotational speeds of fans 41, 42, 43, and 44 in accordance with the heat radiation amounts from the inside. Therefore, a distribution (non-uniformity) of amounts of air (cooling air current) passing through the filter 150 occurs in a plan view, and amounts of dust attached to the filter 150 are not uniform in a plan view.

For example, there may be a case in which more dust is attached to the filter 150 at a location where the three fans 41 are present than a location where the two fans 44 are present. Further, there may be a case in which more dust is attached to the filter 150 at a positive side in the Y axis direction than a negative side in the Y axis direction in a plan view. Further, there may be a case in which the most dust is attached to the filter 150 at a portion for which one fan 41 is present at a positive side in the Y axis direction.

Although the six signal processing cards 31, 32, 33, 34, 35, and 36 are inserted in the frame 20 in the embodiment described as an example here, in a case where the base station apparatus 10 is arranged in a smaller population area, only three signal processing cards 31, 32, and 33 are inserted in the frame 20 and portions in which the signal processing cards 34, 35, and 36 are disposed in FIG. 1 may be voids. In such a case also, a distribution (non-uniformity) of amounts of air passing through the filter 150 occurs in a plan view, and amounts of dust attached to the filter 150 become non-uniform in a plan view. Note that in a case of voids, in order to maintain cooling effects, the negative surface in the Y axis direction is generally covered with a member having a shape that is in accordance with the front face of the signal processing card. At the positive side surface in the Y axis direction, a wiring substrate is provided between the signal processing cards at a Back Wired Board (BWB). Therefore, air does not leak in the Y axis positive direction.

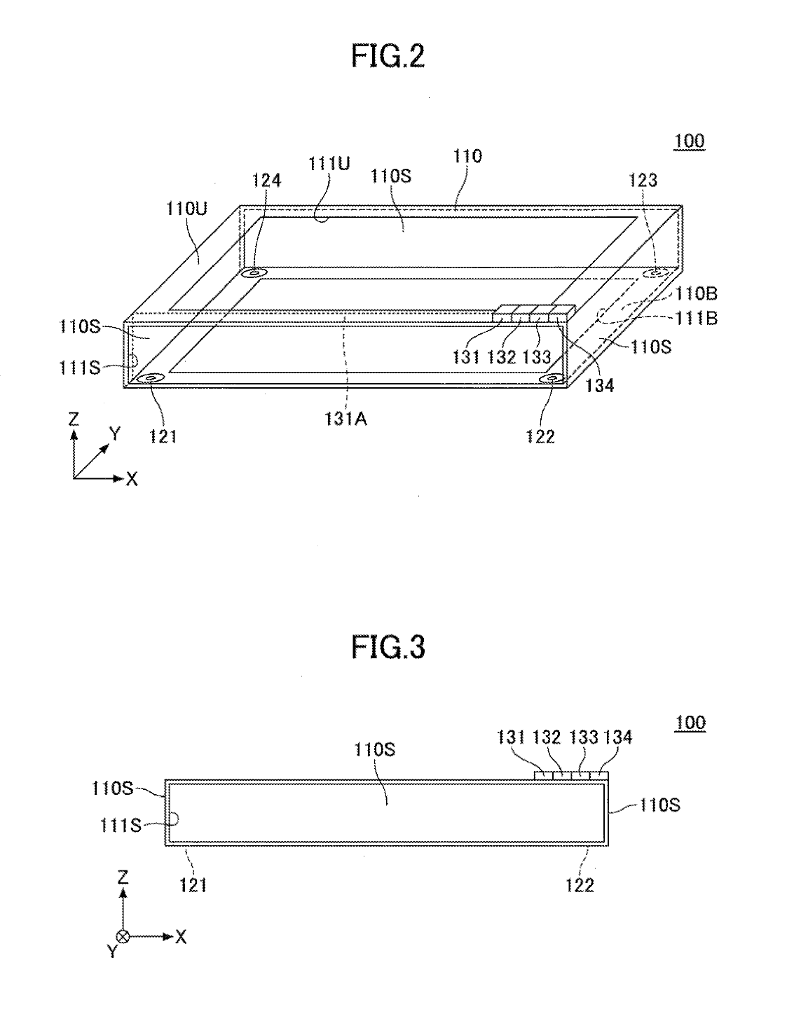

FIG. 2 and FIG. 3 are diagrams illustrating the filter main unit 100. In FIG. 2 and FIG. 3, the conductive rubbers 141, 142, 143, and 144 and the filter 150 are omitted.

The filter main unit 100 includes a filter case 110, sensors 121, 122, 123, and 124, and the terminals 131, 132, 133, and 134.

The filter case 110 is an example of a housing within which the filter 150 is housed. The filter case 110 is made of (conductive) metal such as stainless or aluminum, and includes a bottom surface frame 110B, an upper surface frame 110U, and side surface frames 110S. The filter case 110 is fixed to the frame 20 to be held (maintained) at the frame ground potential.

The bottom surface frame 110B has a rectangular opening 111B, and is a frame part, having a rectangular ring shape rectangular ring shape, that defines the bottom surface of the filter case 110. The bottom surface frame 110B encloses the opening 111B. The opening 111B is an example of a first opening. The upper surface frame 110U has a rectangular opening 111U, and is a frame part, having a rectangular ring shape, that defines the upper surface of the filter case 110. The upper surface frame 110U encloses the opening 111U. The opening 111U is an example of a second opening.

The bottom surface frame 110B and the upper surface frame 110U have the same shape. The position of the opening 111B and the position of the opening 111U are equal to each other in a plan view. Although the opening 111B matches the opening 111U according to the embodiment of the present invention, they are not required to match each other depending on airflow computation. In some cases, it is preferable that the position of the opening 111B does not match the position of the opening 111U. The openings 111B and 111U constitute a flow path of a cooling air current of the filter main unit 100.

The side surface frame 110S is provided, between the bottom surface frame 110B and the upper surface frame 110U, at three surfaces that are a side surface parallel to the YZ plane at the negative side in the X axis direction, a side surface parallel to the YZ plane at the positive side in the X axis direction, and a side surface parallel to the XZ plane at the positive side in the Y axis direction.

At the negative side in the Y axis direction at which the side surface frame 110S is not provided, an opening 111S is provided. The opening 111S is an opening formed on the entire side part at the negative side in the Y axis direction of the filter case 110. The opening 111S is provided in order to insert the filter 150 into the inside of the filter main unit 100.

Note that an outer size of the filter 150 is set to be a value such that the filter 150 can move several millimeters in the Z axis direction in a state of being housed inside the filter main unit 100.

The sensors 121, 122, 123, and 124 are respectively provided on the four corners on the upper surface of the bottom surface frame 110B. The respective sensors 121, 122, 123, and 124 are provided in order to detect plugging at the four corners and have terminals.

The terminals of the sensors 121, 122, 123, and 124 are respectively insulated from the bottom surface frame 110B, and coupled to the terminals 131, 132, 133, and 134 through four wires. In FIG. 2, a dashed line illustrates a wire 131A that couples the sensor 121 and the terminal 131. For example, the wire 131A is disposed on the lower surface of the upper surface frame 110U, the inside surface of the side surface frame 110S, and the upper surface of the upper surface frame 110B, in a state of being insulated from the upper surface frame 110U, the side surface frames 110S, and the bottom surface frame 110B. Wires that couple the sensors 122, 123, and 124 and the terminals 132, 133, and 134 are similarly disposed.

The terminals 131, 132, 133, and 134 are disposed, on the upper surface of the upper surface frame 110U, at the corner part, which is located at the positive side in the X axis direction and at the negative side in the Y axis direction. On the terminals 131, 132, 133, and 134, the conductive rubbers 141, 142, 143, and 144 (see FIG. 1) are respectively attached. The terminals 131 to 134 and the conductive rubbers 141 to 144 are installed at the positive side in the X axis direction because the monitoring control card 200 that has a circuit for detecting/reporting plugging of a dust-proof filter is mounted on a surface above (positive side in the Z axis direction). In a case where a monitoring control card is mounted on a position at the negative side in the X axis direction, the terminals and the conductive rubbers are mounted at the negative side that is corresponding to the position where the monitoring control card is mounted.

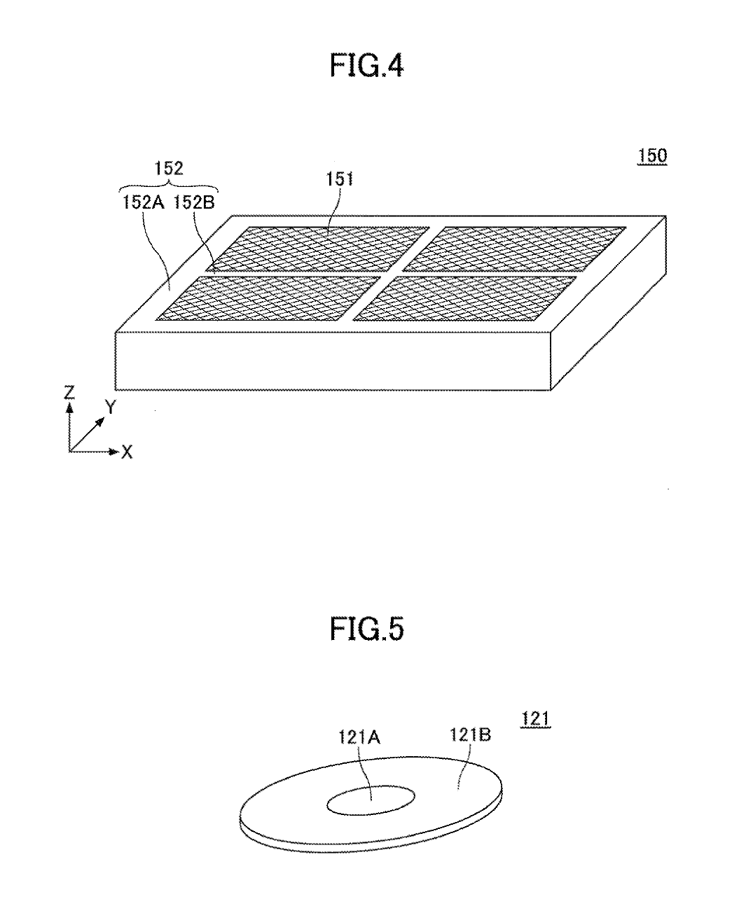

FIG. 4 is a diagram illustrating the filter 150.

The filter 150 includes a filter part 151 and a filter frame 152. The filter 150 is housed inside the filter case 110 (see FIG. 2 and FIG. 3). The filter 150 removes dust included in air (cooling air current) flowing from the lower surface side in accordance with driving of the cooling fan 40, and causes the cooling air current to flow from the upper surface side to the signal processing card 30 (31, 32, 33, 34, 35, and 36) and the monitoring control card 200.

For example, the filter part 151 may be a material such as a mesh-like or flocculent synthetic (fiber) having a predetermined grade dust-proofness. The filter part 151 has a rectangular shape in a plan view, and is held to be planar by the frame 152. In other words, the frame 152 may hold the periphery of the filter part 151 in a plan view. Note that the filter part 151 is not required to be rectangular in a plan view depending on a relationship of the signal processing card sizes. In the described specification, the filter part 151 has a rectangular shape.

The frame 152 includes a rectangular frame part 152A and a sub-frame 152B. The rectangular frame part 152A is a metal frame that covers (encloses) the side surfaces (four surfaces) of the filter part 151, and in a rectangularly ring shape covers (encloses) the edges of the lower surface and the upper surface of the filter part 151. At a section extending in the X axis direction, a cross sectional shape of the rectangular frame part 152A is a U-shape in a plane parallel to the YZ plane. At a section extending in the Y axis direction, a cross sectional shape of the rectangular frame part 152A is a U-shape in a plane parallel to the XZ plane. That is, the rectangular frame part 152A holds the edges of the lower surface and the upper surface of the filter part 151 and holds (retains) the side surfaces (four surfaces) of the filter part 151.

The sub-frame 152B is provided, at the upper surface side of the filter part 151, in a cross shape at the central part in a plan view. The sub-frame 152B is fixed to the rectangular frame part 152A. The sub-frame 152B is provided in order to enhance stiffness of the rectangular frame part 152A. Further, the sub-frame 152B holds (retains) the filter part 151 such that the filter part 151, which receives an airflow pressure of the cooling air current from the lower side, does not expand toward the upper side. Note that the sub-frame 152B may be provided at the lower surface, or may be provided at both the upper side and the lower side. Depending on a filter material, the sub-frame 152B may be omitted in a case where the filter part 151 does not deform even when receiving the cooling air current from the lower side.

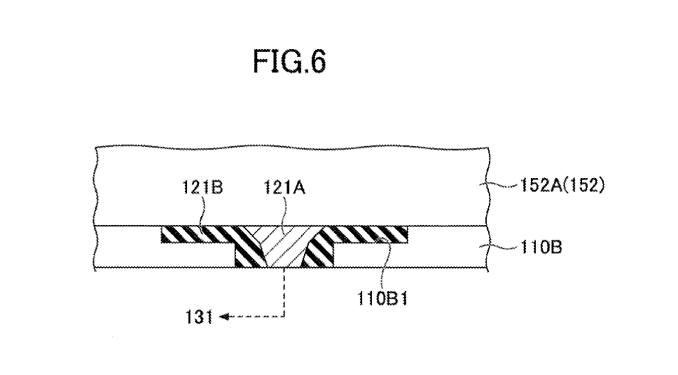

FIG. 5 and FIG. 6 are diagrams illustrating the sensor 121. FIG. 6 illustrates a cross section in which the rectangular frame part 152A of the frame 152 is in contact with the upper surface of the sensor 121. Note that because all the sensors 121, 122, 123, and 124 have the same configuration, only the sensor 121 will be described here.

The sensor 121 has a terminal 121A and a ring cover 121B. The sensor 121 is fitted to the inside of a through hole 110B1 provided on the bottom surface frame 110B. The through hole 110B1 is a circular through hole in a plan view. A step-like inner surface of the through hole 110B1 is made such that its diameter at the upper side is greater than its diameter at the lower side.

A side surface of the terminal 121A is covered by the ring cover 121B. The upper surface and the bottom surface of the terminal 121A are flush with the upper surface and the lower surface of the bottom surface frame 110B. The lower end of the terminal 121A is coupled to the terminal 131 through the wire 131A (see FIG. 2).

The terminal 121A is made of stainless, aluminum, or copper, for example. The ring cover 121B is made of resin, and insulates the bottom surface frame 110B and the terminal 121A. The terminal 121A is insulated from the bottom surface frame 110B by the ring cover 121B such that the terminal 121A is held at a floating potential. The ring cover 121B is an example of an insulation part.

Because the upper surface of the terminal 121A is flush with the upper surface of the bottom surface frame 110B, when the filter 150 is inserted inside the filter case 110, the lower surface of the rectangular frame part 152A of the frame 152 contacts the upper surface of the terminal 121A. Because the lower surface of the rectangular frame part 152A is also in contact with the upper surface of the bottom surface frame 110B, the terminal 121A is coupled to the bottom surface frame 110B via the rectangular frame part 152A. Because the bottom surface frame 110B is held at the frame ground potential, the terminal 121A is held (maintained) at the frame ground potential in a state of being coupled to the bottom surface frame 110B via the rectangular frame part 152A.

Therefore, in the state of being coupled to the bottom surface frame 110B via the rectangular frame part 152A, an electric potential detected by the sensor 121 is the frame ground potential. This is similarly applied to the sensors 122, 123, and 124.

The filter 150 receives an airflow pressure of the cooling air current from the lower side. When the filter 150 is plugged and a force (force acting toward the upper side) due to the wind pressure received by the filter 150 becomes greater than the gravity force applied to the filter 150, the filter 150 floats up from the bottom surface frame 110B.

Because the amount of dust attached to the filter 150 is not uniform in a plan view, the force due to the airflow pressure force received by the filter 150 is not uniform in a plan view. Hence, in a plugged state, the filter 150 may receive a planarly non-uniform airflow pressure, and the rectangular frame part 152A may separate from the surface of any of the sensors 121, 122, 123, and 124.

In such a state, an electric potential detected by any sensor, which is away from the rectangular frame part 152A, of the sensors 121, 122, 123, and 124 changes to the floating potential from the frame ground potential. According to the embodiment, a change of the electric potential of any of the sensors 121, 122, 123, and 124 is monitored to detect plugging of the filter 150.

The filter 150 may have a weight such that in a state in which the filter 150 is not plugged (dust is not attached), even when receiving the airflow pressure of the cooling air current, the rectangular frame part 152A is in contact with the sensors 121, 122, 123, and 124 and does not float. Further, the filter 150 may have the weight such that the filter 150 is floated by the airflow pressure when plugging occurs to an extent requiring an operation for removing attached dust or an operation for replacing the filter 150. In other words, the filter 150 may be made such that the filter 150 is floated by the air flowing from the lower side to the upper side caused by the cooling fan 40 when a predetermined or more amount of dust is attached to the filter 150. Further, the filter 150 may be made such that when the amount of dust attached to the filter 150 is less than the predetermined amount, the filter 150 is not floated by the air flowing from the lower side to the upper side.

Such a weight of the filter 150 may be obtained (calculated) through an experiment or simulation using an air speed of the cooling air current and an air resistance of the filter 150 at the time when the plugging occurs to an extent requiring an operation for removing dust or an operation for replacing the filter 150.

FIG. 7 is a diagram illustrating a configuration of a monitoring system of the filter main unit 100 and the monitoring control card 200. FIG. 7 illustrates the filter case 110, the terminals 131, 132, 133, and 134, and the filter 150 of the filter main unit 100, the nodes 211, 212, 213, and 214, pull-up resisters 221, 222, 223, and 224, an OR circuit 230, and the warning lamp 240 of the monitoring control card 200.

The pull-up resisters 221, 222, 223, and 224, and the OR circuit 230 are built in the monitoring control card 200. The monitoring control card 200 includes the warning lamp 240 disposed on its outer surface. The pull-up resisters 221, 222, 223, and 224 are respectively provided to branch off from between the nodes 211, 212, 213, and 214 and the input terminals of the OR circuit 230.

To the four input terminals of the OR circuit 230, the nodes 211, 212, 213, and 214 are respectively coupled. An output terminal of the OR circuit 230 is coupled to the warning lamp 240. Electric potentials of the nodes 211, 212, 213, and 214 are input to the OR circuit 230, and a logical addition of the four electric potentials is output. In other words, the OR circuit 230, which is an example of an electric potential detecting part, may output a logical addition of the electric potentials detected by the sensors 121, 122, 123, and 124. For example, the warning lamp 240 may be a Light Emitting Diode (LED). The warning lamp 240 does not light up when the output of the OR circuit 230 is the Low (L) level, and lights up when the output is the High (H) level. Note that the warning lamp 240 is just an example of a reporting unit. Another reporting unit such as a unit that uses sound or a unit that notifies a higher-level device may be used.

In a state in which the filter 150 is not plugged (dust is not attached to the filter 150), because the electric potentials of the nodes 211, 212, 213, and 214 are the frame ground potential, the output of the OR circuit 230 is the L level. Accordingly, in the state in which the filter 150 is not plugged (dust is not attached), the OR circuit 230 does not light up the warning lamp 240.

Note that even when dust is attached to the filter 150 because of having used the filter main unit 100, the output of the OR circuit 230 is the L level and the warning lamp 240 does not light up unless the amount of dust reaches a predetermined amount requiring an operation for removing dust attached to the filter 150 or an operation for replacing the filter 150.

When plugging occurs to an extent requiring an operation for removing dust attached to the filter 150 or an operation for replacing the filter 150, the rectangular frame part 152A of the filter 150 floats to be away from any one or more of the sensors 121, 122, 123, and 124.

In this way, the electric potential(s) of corresponding node(s) of the nodes 211, 212, 213, and 214 is pulled up, by the corresponding pull-up resistor(s) of the pull-up resistors 221, 222, 223, and 224, from the frame ground potential to be the H level.

As a result of the above, the output of the OR circuit 230 changes to be the H level and the warning lamp 240 lights up. For example, in a state in which the rectangular frame part 152A floats to be away from the three sensors 121, 122, and 123 and be in contact with only the sensor 124, the electric potentials of the nodes 211, 212, and 213 become the H level and the electric potential of the node 214 is held at the L level. Therefore, in this state, the output of the OR circuit 230 becomes the H level and the warning lamp 240 lights up. Because of using the OR circuit 230, the filter apparatus 300 lights up the warning lamp 240 when the rectangular frame part 152A separates from any one or more of the sensors 121, 122, 123, and 124.

Accordingly, when the warning lamp 240 lights up, a user of the filter apparatus 300 may perform work of removing the dust attached to the filter 150 or work of replacing the filter 150.

In other words, the OR circuit 230 may detect, through the sensors 121, 122, 123, and 124, the change of the electric potential from the electric potential (L level) in a first state, in which the frame 152 is in contact with the upper surface of the bottom surface frame 110B and the sensors 121 to 124, to the electric potential (H level) in a second state, in which the frame 152 is floated to be away from any one or more of the sensors 121 to 124 by the cooling air current supplied to the signal processing card 30 via the filter part 150. The OR circuit 230 may output a first logical value (L level) in the first state, in which the amount of dust attached to the filter part 151 is less than a predetermined amount, and output a second logical value (H level) in the second state in which the amount of dust attached to the filter part 151 is greater than or equal to the predetermined amount. Note that in the first state in which the amount of dust attached to the filter part 151 is less than the predetermined amount, the frame 152 does not float even when the cooling air current is supplied.

As described above, according to the embodiment, it is possible to provide the filter apparatus 300 that can accurately detect a situation of plugging and a method for determining plugging of the filter apparatus 300 even in a situation in which amounts of air passing through the filter 150 are distributed (non-uniform) in a plan view and amounts of dust attached to the filter 150 are not uniform in a plan view.

Note that although the four sensors 121, 122, 123, and 124 are used in the described embodiment, the number of sensors may be two. In a case where the two sensors are used, it is most effective to use the sensors 121 and 123 or the opposite sensors 122 and 124 that are located at diagonally opposite positions. In other words, two sensors may be used that are disposed on the diagonally opposite corners of the four corners of the upper surface of the bottom surface frame 110B. Note that the situation of plugging can be accurately detected by using any two of the sensors 121, 122, 123, and 124 even in a situation in which the amounts of dust attached to the filter 150 is not uniform in a plan view. Additionally, any three of the four sensors 121, 122, 123, and 124 may be used.

Further, although the filter apparatus 300 is used in the base station apparatus 10 in the described embodiment, the filter apparatus 300 may be applied to apparatuses other than the base station apparatus 10 if the apparatuses require removing dust of a cooling air current and a distribution of dust is not uniform in a plan view. That is, the filter apparatus 300 may be used for obtaining (collecting) dust of a cooling air current supplied to an electronic device, other than the signal processing card 30 (31, 32, 33, 34, 35, and 36), in which the air volume required for heat radiation is not planarly uniform. Additionally, the signal processing card 30 may be a single one.

Further, although the change of the electric potentials of the four sensors 121, 122, 123, and 124 is detected (determined) by the OR circuit 230 in the embodiment described above, a circuit other than the OR circuit 230 may be used if the circuit can detect that any one of the electric potentials of the four sensors 121, 122, 123, and 124 changes from the L level (frame ground potential) to the H level.

Although an example of a filter apparatus and a method for determining plugging of a filter apparatus according to the embodiment of the present invention has been described above, the present invention is not limited to the embodiment specifically disclosed and various variations and modifications may be made without departing from the scope of the present invention.

All examples and conditional language provided herein are intended for pedagogical purposes of aiding the reader in understanding the invention and the concepts contributed by the inventors to further the art, and are not to be construed as limitation to such specifically recited examples and conditions, nor does the organization of such examples in the specification relate to a showing of superiority and inferiority of the invention. Although one or more embodiments of the present invention have been described in detail, it should be understood that various changes, substitutions, and alterations could be made hereto without departing from the spirit and scope of the invention.

What is claimed is:

1. A filter apparatus comprising:
a conductive housing disposed below an electronic device to which a cooling air current is supplied from a lower side to an upper side, the housing including a bottom surface frame having a first opening and including an upper surface frame having a second opening opposite to the first opening;
a plurality of terminals provided on an upper surface side of the bottom surface frame of the housing, the plurality of terminals being insulated from the housing;
a filter disposed inside the housing between the first opening and the second opening, the filter including a filter part configured to remove dust of the cooling air current and including a filter frame retaining a periphery of the filter part in a plan view; and
an electric potential detecting part coupled to the plurality of terminals and configured to detect electric potentials of the plurality of terminals, the electric potential detecting part being configured to detect a change of an electric potential, in a state in which the cooling air current is supplied to the electronic device via the filter part, with respect to an electric potential in a state in which the filter frame is in contact with an upper surface of the bottom surface frame and the plurality of terminals.

2. The filter apparatus according to claim 1,
wherein the electric potential detecting part is an OR circuit configured to output a logical addition of the electric potentials of the plurality of terminals, and
wherein the OR circuit is configured to output a first logical value in the state in which the filter frame is in contact with the upper surface of the bottom surface frame and the plurality of terminals, and is configured to output a second logical value in a state in which a predetermined amount or more of dust is attached to the filter part and the cooling air current is supplied to the electronic device via the filter part.

3. The filter apparatus according to claim 1, wherein the filter further includes a sub-frame, coupled to the filter frame, the sub-frame retaining a central part of the filter part.

4. The filter apparatus according to claim 1,
wherein each of the first opening and the second opening has a rectangular shape in a plan view,
wherein the bottom surface frame and the upper surface frame have respectively rectangular ring shapes enclosing the first opening and the second opening,
wherein the filter part has a rectangular shape in a plan view, and the filter frame has a rectangular ring shape enclosing the filter part having the rectangular shape, and
wherein the plurality of terminals are disposed on any of four corners of the upper surface of the bottom surface frame having the rectangular ring shape.

5. The filter apparatus according to claim 4, wherein the plurality of terminals are
two terminals respectively disposed on two diagonally opposite corners of the four corners of the upper surface of the bottom surface frame having the rectangular ring shape,
three terminals respectively disposed on three corners of the four corners of the upper surface of the bottom surface frame having the rectangular ring shape, or
four terminals respectively disposed on the four corners of the upper surface of the bottom surface frame having the rectangular ring shape.

6. A method for determining plugging of a filter apparatus, the filter apparatus including a conductive housing disposed below an electronic device to which a cooling air current is supplied from a lower side to an upper side, the housing including a bottom surface frame having a first opening and including an upper surface frame having a second opening opposite to the first opening; a plurality of terminals provided on an upper surface side of the bottom surface frame of the housing, the plurality of terminals being insulated from the housing; and a filter disposed inside the housing between the first opening and the second opening, the filter including a filter part configured to remove dust of the cooling air current and including a frame retaining a periphery of the filter part in a plan view, the method comprising:
determining the plugging of the filter based on a change of an electric potential, in a state in which the cooling air current is supplied to the electronic device via the filter part, with respect to an electric potential in a state in which the filter frame is in contact with an upper surface of the bottom surface frame and the plurality of terminals.
